(19) United States
(12) Patent Application Publication
(10) Pub. No.: US 2014/0175615 A1
(43) Pub. Date: Jun. 26, 2014

(54) SEMICONDUCTOR DEVICE AND METHOD FOR MANUFACTURING THE SAME

(71) Applicant: Mitsubishi Electric Corporation, Tokyo (JP)

(72) Inventors: Yoichi Nogami, Tokyo (JP); Yoshitsugu Yamamoto, Tokyo (JP); Yoshinori Yokoyama, Tokyo (JP); Shinnosuke Soda, Tokyo (JP)

(73) Assignee: Mitsubishi Electric Corporation, Tokyo (JP)

(21) Appl. No.: 14/036,009

(22) Filed: Sep. 25, 2013

(30) Foreign Application Priority Data
Dec. 20, 2012 (JP) 2012-277951

(51) Int. Cl. H01L 23/29; H01L 21/56

(52) U.S. Cl. CPC H01L 23/291; H01L 21/56
USPC 257/621; 438/778

(57) ABSTRACT

A method for manufacturing a semiconductor device includes: forming a semiconductor element on a main surface of a substrate; forming a low melting glass film having a melting point of 450° C. or less on the main surface and the semiconductor element; heat treating the substrate while pressing the low melting glass film toward the main surface of the substrate with a pressurizing jig that is insulating or semi-insulating, and sintering the low melting glass film; and leaving the pressurizing jig on the low melting glass film after sintering the low melting glass film.

### BACKGROUND OF THE INVENTION

1. Field of the Invention

The present invention relates to a semiconductor device and method for manufacturing the same having high moisture resistance and high mechanical strength.

2. Background Art

Since general-purpose high frequency semiconductor devices, including field effect transistors of compound semiconductor such as GaAs or GaN, etc., have rapidly become prevalent, there has been a great need to reduce their cost. In order to meet this need, low-cost molded packages have been adopted instead of conventional fully hermetic metal packages. However, the use of a non-hermetic package such as a molded package requires that the semiconductor device contained therein be highly moisture resistant in order to prevent various types of degradation due to moisture. A conventional method for providing the semiconductor device with moisture resistance has been to prevent infiltration of moisture into the semiconductor device by covering the surfaces of the semiconductor elements and metal films in the semiconductor device using a thick insulating film of SiN, etc. formed by plasma CVD, etc.

Insulating films formed by plasma CVD or the like, however, may tend to absorb moisture, depending on the conditions under which they are formed. Further, the thick insulating film, unlike a thin insulating film, may peel off due to stress change resulting from absorption of slight moisture by the film. Further, there will be degradation in the covering ability and quality of the film at step portions associated with the configurations of the transistors of the semiconductor device. As a result, the thick insulating film is likely to transmit and absorb moisture, meaning that the film cannot fully prevent infiltration of moisture into the transistors. Therefore, it has been difficult to fully prevent various types of degradation due to such moisture infiltration.

In order to address the above problem of moisture resistance, a passivation method has been proposed in which semiconductor elements are coated with a low melting glass composition (see, e.g., Japanese Laid-Open Patent Publication No. S59-150428).

### SUMMARY OF THE INVENTION

In the case of high frequency semiconductor devices, for instance, semiconductor elements formed on the main surface of the substrate typically have an elevated step projecting a maximum of as much as approximately 10 μm from the main surface. Therefore, it has been found difficult to fully cover such elevated steps, even with a low melting glass composition, resulting in an inability to achieve the desired moisture resistance.

Further, chip scale package (CSP) techniques have been increasingly applied to, e.g., high frequency semiconductor devices in order to reduce their cost. However, in the case of high frequency high power semiconductor devices, which generate considerable heat, the substrate is configured to have a reduced thickness, e.g., 30-150 μm, in order to enhance heat dissipation from it. This prevents the chip from maintaining the desired mechanical strength.

In view of the above-described problems, an object of the present invention is to provide a semiconductor device and method for manufacturing the same having high moisture resistance and high mechanical strength.

According to the present invention, a method for manufacturing a semiconductor device includes: forming a semiconductor element on a main surface of a substrate; forming a low melting glass film having a melting point of 450° C. or less on the main surface and the semiconductor element; heat treating the substrate while pressing the low melting glass film toward the main surface of the substrate using a pressurizing jig being insulating or semi-insulating, so as to sinter the low melting glass film; and leaving the pressurizing jig on the low melting glass film after sintering the low melting glass film.

The present invention makes it possible to provide a semiconductor device and method for manufacturing the same having high moisture resistance and high mechanical strength.

Other and further objects, features and advantages of the invention will appear more fully from the following description.

### BRIEF DESCRIPTION OF THE DRAWINGS

FIG. 1 is a top view of a semiconductor device in accordance with a first embodiment of the present invention.

FIG. 2 is a cross-sectional view taken along line I-II of FIG. 1.

FIGS. 3 and 4 are cross-sectional views showing the manufacturing process of the semiconductor device of the first embodiment.

FIG. 5 is a top view of a semiconductor device in accordance with a second embodiment of the present invention.

FIG. 6 is a cross-sectional view taken along line I-II of FIG. 5.

### DETAILED DESCRIPTION OF THE PREFERRED EMBODIMENTS

A semiconductor device and method for manufacturing the same according to the embodiments of the present invention will be described with reference to the drawings. The same components will be denoted by the same symbols, and the repeated description thereof may be omitted.

### First Embodiment

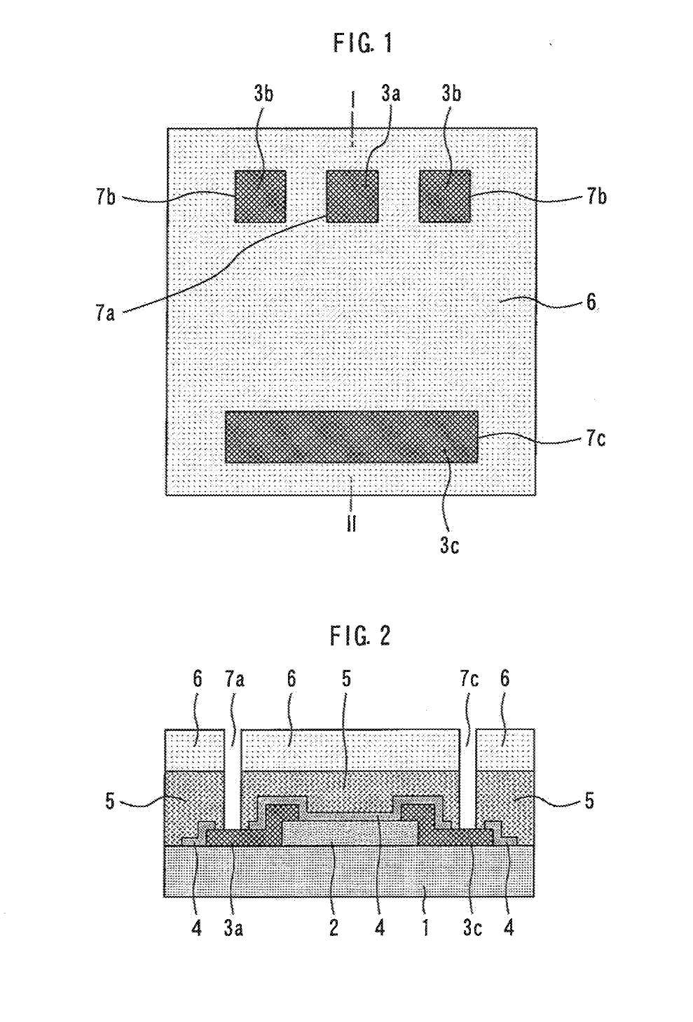

FIG. 1 is a top view of a semiconductor device in accordance with a first embodiment of the present invention. FIG. 2 is a cross-sectional view taken along line

I-II of FIG. 1. The substrate 1 shown in FIGS. 1 and 2 is a semiconductor substrate of Si, GaAs, GaN, InP, or SiC, etc., or an insulating substrate of sapphire or ceramic. A field effect transistor 2 is formed on the main surface of the substrate 1. A gate electrode 3a, a source electrode 3b, and a drain electrode 3c are also formed on the main surface of the substrate 1 and are connected to the gate, the source, and the drain, respectively, of the field effect transistor 2. It should be noted that the details of the transistor structure have been omitted from FIGS. 1 and 2. Further, the field effect transistor 2 may be replaced by any other suitable semiconductor element such as a bipolar transistor element.

An SiN film 4 and a low melting glass film 5 having a melting point of 450° C. or less cover the main surface of the substrate 1 and the surface of the field effect transistor 2. The low melting glass film 5 is vanadium-based glass, bismuth-based glass, lead-based glass, or lead fluoride-based glass. These materials can be sintered at 400° C. or less and have high moisture resistance.

A pressurizing jig 6 is disposed on the low melting glass film 5. The pressurizing jig 6 is insulating or semi-insulating and may be, e.g., a high melting glass substrate. Openings 7a, 7b, and 7c penetrate through the low melting glass film 5 and the pressurizing jig 6 so as to expose portions of the gate electrode 3a, the source electrode 3b, and the drain electrode 3c.

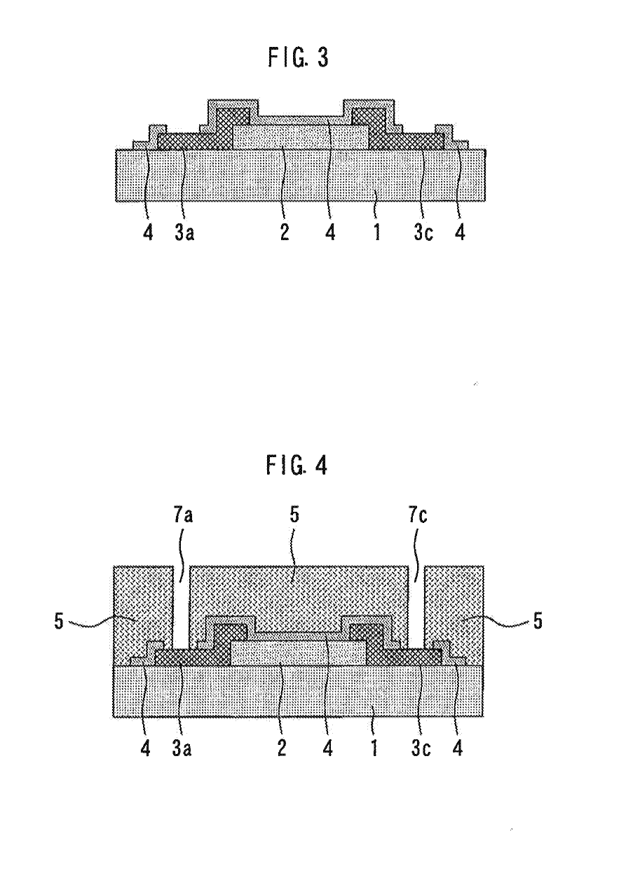

A method of manufacturing a semiconductor device in accordance with the present embodiment will now be described with reference to the accompanying drawings. FIGS. 3 and 4 are cross-sectional views showing the manufacturing process of the semiconductor device of the first embodiment.

First, as shown in FIG. 3, the field effect transistor 2 is formed on the main surface of the substrate 1. The gate electrode 3a, the source electrode 3b, and the drain electrode 3c are then formed on the main surface of the substrate 1 using a metal film in such a manner that these electrodes are connected to their respective terminals of the field effect transistor 2. The SiN film 4 is then formed by plasma CVD so as to cover the main surface of the substrate 1 and the surface of the field effect transistor 2. Further, contact holes are formed in the SiN film 4 on the gate electrode 3a, the source electrode 3b, and the drain electrode 3c.

Next, as shown in FIG. 4, a low melting glass paste or the like is applied to the main surface of the substrate 1 and the surface of the field effect transistor 2 by means of screen printing using a screen mask, thereby forming the low melting glass film 5. It should be noted that the screen mask masks portions of the gate electrode 3a, the source electrode 3b, and the drain electrode 3c so that the low melting glass film 5 is not formed on these portions. The substrate 1 is then heat treated to presinter and thereby degas the low melting glass film 5.

Next, as shown in FIG. 1, the substrate 1 is heat treated while pressing the low melting glass film 5 toward the main surface of the substrate 1 using the pressurizing jig 6, so as to sinter the low melting glass film 5. The pressurizing jig 6 is left on the low melting glass film 5 after the sintering of the film. It should be noted that the pressurized jig 6 has formed therein holes partially forming the openings 7a, 7b, and 7c for exposing portions of the gate electrode 3a, the source electrode 3b, and the drain electrode 3c.

In accordance with the present embodiment, the low melting glass film 5 is pressure sintered using the pressurizing jig 6. Therefore, even if the field effect transistor 2 formed on the main surface of the substrate 1 has an elevated step projecting 10 μm or more, the low melting glass film 5 can be formed to fully cover the main surface of the substrate 1 and the surface of the field effect transistor 2. This means that no moisture infiltration path is unexpectedly formed to allow moisture into the field effect transistor 2, resulting in high moisture resistance of the semiconductor device.

Further, since the pressurizing jig 6 is left as a part of the semiconductor device after using the jig 6 for pressure sintering, the semiconductor device has high mechanical strength. This is advantageous, especially when the semiconductor device is a high power semiconductor device wherein the thickness of the substrate 1 has been reduced to a few tens of microns by grinding the bottom surface of the substrate 1 in order to achieve the desired heat dissipation from the field effect transistor 2.

Second Embodiment

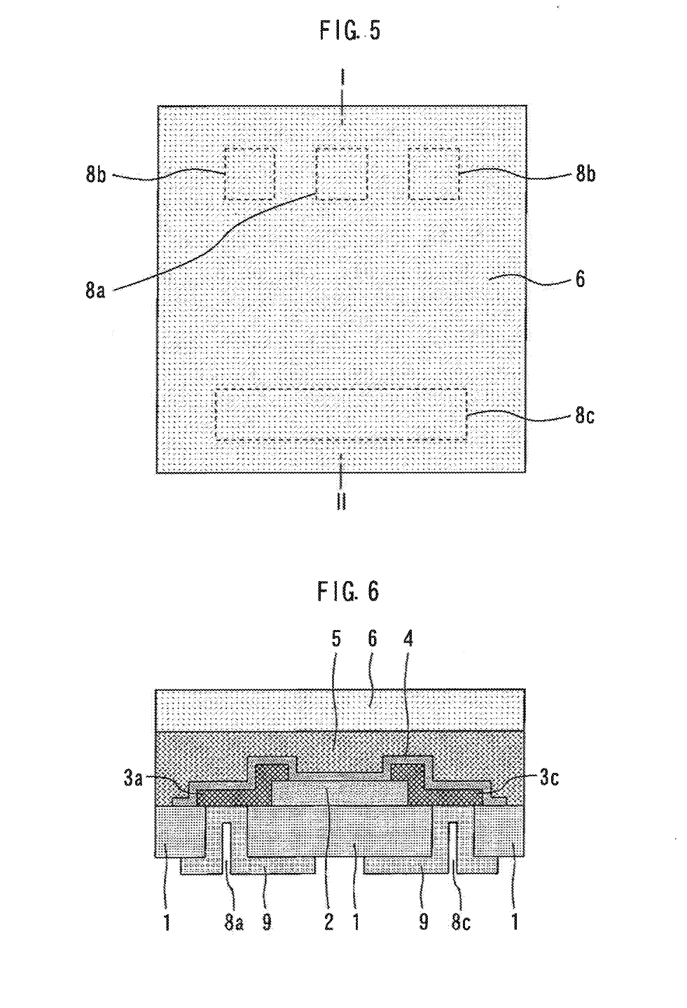

FIG. 5 is a top view of a semiconductor device in accordance with a second embodiment of the present invention. FIG. 6 is a cross-sectional view taken along line I-II of FIG. 5. Via holes 8a, 8b, and 8c penetrate a substrate 1 from the bottom surface to the top surface thereof, exposing portions of a gate electrode 3a, a source electrode 3b, and a drain electrode 3c formed on the substrate 1. Three bottom surface metal films 9 are formed on the bottom surface side of the substrate 1. A first one of the metal films 9 extends through the via hole 8a, is connected to the gate electrode 3a, and serves as a bottom surface gate electrode. A second one of the metal films 9 extends through the via hole 8b, is connected to the source electrode 3b, and serves as a bottom surface source electrode. The third one of the metal films 9 extends through the via hole 8c, is connected to the drain electrode 3c, and serves as a bottom surface drain electrode. All the other components are the same as those described in connection with the first embodiment. This semiconductor device has the same advantages as described above in connection with the first embodiment. It should be noted that as shown in FIG. 6, a pressurizing jig 6 forms the entire top surface of the semiconductor device and is exposed to the environment.

Although the above embodiments have been described in connection with high frequency semiconductor elements, it is to be understood that the present invention may be applied to other semiconductor elements including two-terminal semiconductor elements, such as rectifier diodes and PIN diodes, optical semiconductor elements, such as solar cells, photodiodes, LEDs, semiconductor lasers, and CCDs, and Si-based and GaAs-based semiconductor integrated circuits.

Obviously many modifications and variations of the present invention are possible in the light of the above teachings. It is therefore to be understood that within the scope of the appended claims the invention may be practiced otherwise than as specifically described.

The entire disclosure of Japanese Patent Application No. 2012-277951, filed on Dec. 20, 2012, including specification, claims, drawings, and summary, on which the Convention priority of the present application is based, is incorporated herein by reference in its entirety.

1. A method for manufacturing a semiconductor device comprising:
forming a semiconductor element on a main surface of a substrate;
forming a low melting glass film having a melting point of 450° C. or less on the main surface and the semiconductor element;
heat treating the substrate while pressing the low melting glass film toward the main surface of the substrates with a pressurizing jig that is insulating or semi-insulating, and sintering the low melting glass film; and
leaving the pressurizing jig on the low melting glass film after sintering the low melting glass film.

2. A semiconductor device comprising:
a substrate having a main surface;
a semiconductor element on the main surface;
a low melting glass film having a melting point of 450° C. or less on the main surface and on the semiconductor element; and
a pressurizing jig that is insulating or semi-insulating disposed on the low melting glass film.

3. The semiconductor device according to claim 2, wherein the low melting glass film is selected from the group consisting of vanadium-based glass, bismuth-based glass, lead-based glass, and lead fluoride-based glass.

4. The semiconductor device according to claim 2, wherein the substrate is a semiconductor substrate or an insulating substrate.

5. The semiconductor device according to claim 2, further comprising:
an electrode on the main surface and connected to the semiconductor element; and
an opening penetrating through the low melting glass film and the pressurizing jig and exposing a portion of the electrode.

6. The semiconductor device according to claim 2, further comprising:
an electrode on the main surface and connected to the semiconductor element;
a via hole penetrating through the substrate and exposing a portion of the electrode; and
a metal film on a bottom surface side of the substrate, extending through the via hole, and connected to the electrode.
